(19) United States
(12) Patent Application Publication
(10) Pub. No.: US 2014/0299362 A1
(43) Pub. Date: Oct. 9, 2014

(54) STRETCHABLE ELECTRIC DEVICE AND MANUFACTURING METHOD THEREOF

(71) Applicant: Electronics and Telecommunications Research Institute, Daejeon (KR)

(72) Inventors: Chan Woo PARK, Daejeon (KR); Jae Bon KOO, Daejeon (KR); Soon-Won JUNG, Daejeon (KR); Sang Chul LIM, Daejeon (KR); Ji-Young OH, Daejeon (KR); Bock Soon NA, Daejeon (KR); Sang Seok LEE, Sejong (KR); Hye Yong CHU, Daejeon (KR)

(73) Assignee: Electronics and Telecommunications Research Institute, Daejeon (KR)

(21) Appl. No.: 14/244,087

(22) Filed: Apr. 3, 2014

(30) Foreign Application Priority Data
Apr. 4, 2013 (KR) 10-2013-0036891
Oct. 14, 2013 (KR) 10-2013-0122110

(51) Int. Cl. H05K 1/02; H05K 3/32; H05K 1/03

(52) U.S. Cl. CPC H05K 1/028; H05K 1/0393; H05K 3/32; H05K 1/181
USPC 174/254; 29/832

(57) ABSTRACT

Provided are a stretchable electric circuit and a manufacturing method thereof The method for manufacturing the stretchable electric circuit includes forming a mold substrate, forming a stretchable substrate having a first flat surface and a first corrugated surface outside the first flat surface on the mold substrate, removing the mold substrate, forming a corrugated wire on the first corrugated surface, and forming an electric device connected to the corrugated wire on the first flat surface.

### CROSS-REFERENCE TO RELATED APPLICATIONS

This U.S. non-provisional patent application claims priority under 35 U.S.C. §119 of Korean Patent Application Nos. 10-2013-0036891, filed on 4 Apr. 2013, and 10-2013-0122110, filed on 14 Oct. 2013, the entire contents of which are hereby incorporated by reference.

### BACKGROUND OF THE INVENTION

The present invention relates to an electric device and a manufacturing method thereof, and more particularly, a stretchable electric device and a manufacturing method thereof.

Stretchable electric devices may be maintained in electrical function even though a substrate is expended by stress applied from the outside. Stretchable electric device may be applied in various fields such as sensor skins for a robot, wearable communication devices, implantable/attachable bio devices, next generation displays, and the like in addition to simple bendable/flexible devices.

Such a stretchable electric device may have a structure in which a metal wire is stretchable. The metal wire may be transferred onto a surface of a pre-strained stretchable substrate and then be formed in a wave shape by the construction of the stretchable substrate. The metal wire may give stretchability to the electric device. However, the stretchable electric device may be limited in stretchability of the metal wire by an amount of pre-strain initially applied to the substrate. Also, the metal wire having the wave shape may have limitations in that a manufacturing process is complicated when compared to a general semiconductor device manufacturing process, and thus it is difficult to apply a large area and secure reliability.

The other stretchable electric device may include a wire formed of a conductive stretchable material instead of the metal. The conductive stretchable material may include conductive materials such as a conductor polymer, a carbon nanotube, graphene, and the like. However, the conductive stretchable material may have limitations in that the conductive stretchable material has electric resistance greater than that of the metal, in spite of high stretchability, and it is difficult to form a fine pattern having a micrometer size.

Further another stretchable electric device may include a wire having a two-dimensional spring shape. In the wire having the spring shape, a wire manufacturing process may be compatible with the general semiconductor device manufacturing process to reduce manufacturing costs, easily secure reliability, and obtain high conductivity. However, when the spring-shaped wire is stretched, deformation may be locally concentrated at only a specific portion of the wire to cause damage at the specific portion. Thus, the spring-shaped wire may be limited in stretchability.

### SUMMARY OF THE INVENTION

The present invention provides a stretchable electric circuit in which electric devices and corrugated wires are easily formed and a manufacturing method thereof.

The present invention also provides a stretchable electric circuit which is capable of improving operation reliability and life cycle of electric devices and a manufacturing method thereof.

Embodiments of the inventive concept provide methods for manufacturing a stretchable electric circuit, the methods including: forming a mold substrate; forming a stretchable substrate having a first flat surface and a first corrugated surface outside the first flat surface on the mold substrate; removing the mold substrate; forming a corrugated wire on the first corrugated surface; and forming an electric device connected to the corrugated wire on the first flat surface.

In some embodiments, the stretchable substrate may include: a low-stiffness body having the first corrugated surface; and a high-stiffness block disposed in an island shape on the low-stiffness body, the high-stiffness block having the first flat surface.

In other embodiments, the forming of the stretchable substrate may include: forming the high-stiffness block on the mold substrate; and forming the low-stiffness body on the high-stiffness block and the mold substrate.

In still other embodiments, the high-stiffness block may be formed by using a photolithograph process, a printing process, or a bonding process.

In even other embodiments, the low-stiffness body may be formed by using a spin coating process or a dropping process.

In yet other embodiments, the low-stiffness body may be formed of addition-cure liquid silicone rubber.

In further embodiments, the high-stiffness block may be formed of a photopatternable resin.

In still further embodiments, the low-stiffness body may be formed before the mold substrate is removed, and the high-stiffness block may be formed after the mold substrate is removed.

In even further embodiments, the high-stiffness block may be formed by curing the low-stiffness body under the first flat surface by using laser light.

In yet further embodiments, the mold substrate may include: a mold body; and a photoresist layer disposed on the mold body, and the photoresist layer having a second flat surface corresponding to the first flat surface and a second corrugated surface corresponding to the first corrugated surface.

In much further embodiments, the photoresist layer may have a trench having the second flat surface under the second corrugated surface and the high-stiffness block may be formed in the trench.

In still much further embodiments, the forming of the mold substrate may include a photolithograph process and a reflow process.

In even much further embodiments, the forming of the mold substrate may include a photolithograph process using a grayscale photomask.

In yet much further embodiments, the methods may further include forming a stretchable protection layer on the electric device, the corrugated wire, and the stretchable substrate.

In other embodiments of the inventive concept, stretchable electric circuits include: a stretchable substrate having a flat surface and a corrugated surface outside the flat surface; a corrugated wire disposed on the corrugated surface of the stretchable substrate; and an electric device connected to the corrugated wire, the electric device being disposed on the flat surface, wherein the flat surface has hardness greater than that of the corrugated surface.

In some embodiments, the stretchable substrate may include an elastomer.

In other embodiments, the elastomer may include poly-dimethyllesiloxane (PDMS) or polyurethane.

In still other embodiments, the stretchable substrate may include: a low-stiffness body having the corrugated surface; and a high-stiffness block disposed in an island shape on the low-stiffness body, the high-stiffness block having the flat surface.

In even other embodiments, the low-stiffness body may be formed of addition-cure liquid silicone rubber.

In yet other embodiments, the high-stiffness block may be formed of a photopatternable resin.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a plan view of a stretchable electric circuit according to a first embodiment of the inventive concept;

FIG. 2 is a cross-sectional view taken along line IT of FIG. 1;

FIGS. 3 to 8 are cross-sectional views of a method for manufacturing the stretchable electric circuit according to the first embodiment of the inventive concept, on the basis of FIG. 2;

FIG. 9 is a cross-sectional view of a stretchable electric circuit according to another embodiment of the inventive concept;

FIGS. 10 to 15 are cross-sectional views of a method for manufacturing the stretchable electric circuit according to the second embodiment of the inventive concept, on the basis of FIG. 9; and

FIGS. 16 to 18 are cross-sectional views of a method for manufacturing an electric circuit according to a third embodiment of the inventive concept.

### DETAILED DESCRIPTION OF PREFERRED EMBODIMENTS

Foregoing general illustrations and following detailed descriptions are exemplified for providing an additional explanation of claimed inventions. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the specification, it will be understood that when one part is referred to as “including” one component, it can further include another component in addition to the one component. An embodiment described and exemplified herein includes a complementary embodiment thereof. Hereinafter, exemplary embodiments of the inventive concept will be described in detail with reference to the accompanying drawings.

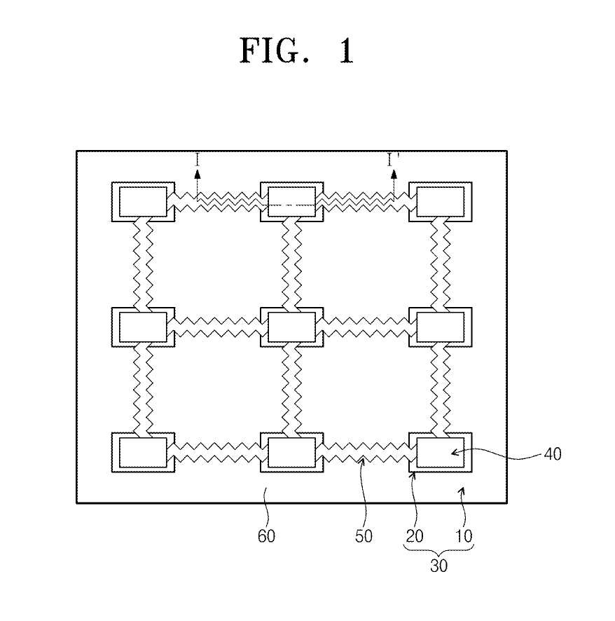

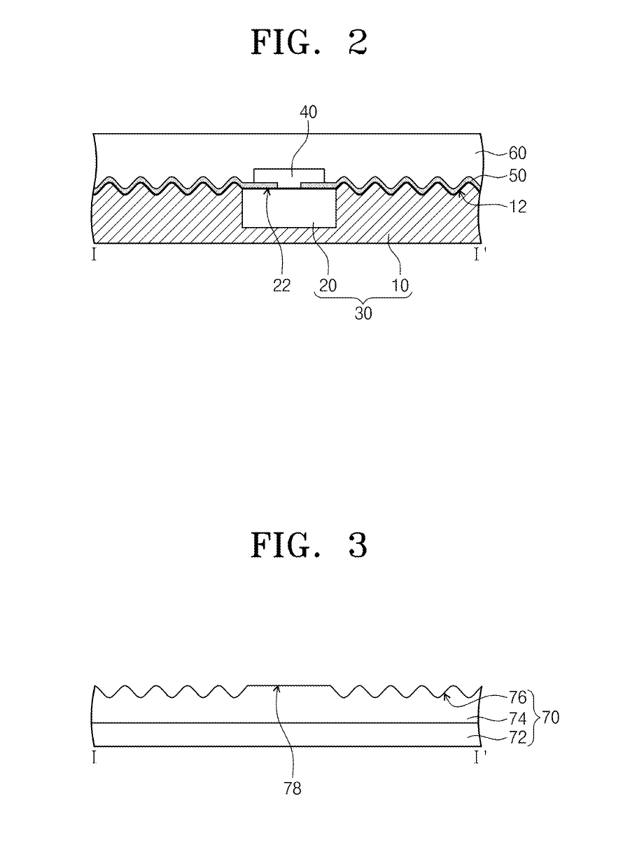

FIG. 1 is a plan view of a stretchable electric circuit according to a first embodiment of the inventive concept. FIG. 2 is a cross-sectional view taken along line I-I′ of FIG. 1.

Referring to FIGS. 1 and 2, a stretchable electric circuit according to the first embodiment of the inventive concept may include a stretchable substrate 30, electric devices 40, corrugated wires 50, and a stretchable protection layer 60.

The stretchable substrate 30 may include a low-stiffness body 10 and high-stiffness blocks 20. The low-stiffness body 10 may have a first corrugated surface 12. The first corrugated surface 12 may be a roughness top surface of the low-stiffness body 10. The low-stiffness body 10 may have stretchability. The low-stiffness body 10 comprises an elastic material. The high-stiffness blocks may be arranged in an island shape on the low-stiffness body 10. Each of the high-stiffness blocks may have mechanical stiffness greater than that of the low-stiffness body 10.

Each of the high-stiffness blocks 20 may be hard and rigid. Each of the high-stiffness blocks 20 may have a first flat surface 22. The stretchable substrate 30 may include an elastomer such as poly-dimethyllesiloxane (PDMS) or polyurethane. For example, the low-stiffness body 10 may include addition-cure liquid silicone rubber (Sylgard 184). Each of the high-stiffness blocks 20 may include a photopatternable resin.

The electric devices 40 and the corrugated wires 50 may be integrally mounted on the stretchable substrate 30. Each of the electric devices 40 may include a thin film transistor and a pixel electrode. The electric devices 40 may be disposed on the first flat surfaces 22 of the high-stiffness blocks 20. The first flat surface 22 may serve as a support surface for stably fixing each of the electric devices 40. The electric devices 40 may be fixed by the high-stiffness blocks 20 even though the low-stiffness body 10 is stretched. That is, the high-stiffness blocks may protect the electric devices 40 from the deformation of the low-stiffness body 10. The high-stiffness blocks may improve operation reliability and life cycle of the electric devices 40.

The corrugated wires 50 may connect the electric devices 40 to each other. The corrugated wires 50 may be disposed on portions of the high-stiffness blocks 20 and on the low-stiffness body 10. The corrugated wires 50 may include a metal such as copper, aluminum, tungsten, nickel, manganese, or silver, a nanotube, or graphene. Each of the corrugated wires 50 may be vertically and horizontally bent along the first corrugated surface 12 on the low-stiffness body 10. Each of the corrugated wires 50 may be horizontally expanded and contracted together with the low-stiffness body 10 by external tension.

The stretchable protection layer 60 covers the stretchable substrate 30, the electric devices 40, and the corrugated wires 50. The stretchable protection layer 60 may include an elastomer, a polymer, an elastic thin film, or an organic thin film.

A method for manufacturing the stretchable electric circuit according to the first embodiment of the inventive concept will be described as follows.

FIGS. 3 to 8 are cross-sectional views of a method for manufacturing the stretchable electric circuit according to the first embodiment of the inventive concept, on the basis of FIG. 2.

Referring to FIG. 3, a mold substrate 70 is prepared. The mold substrate 70 may include a mold body 72 and a photoresist layer 74. The mold body 72 may include a silicon wafer. The photoresist layer 74 may be disposed on the mold body 72. The photoresist layer 74 may have a second corrugated surface 76 and a second flat surface 78. The second corrugated surface 76 and the second flat surface 78 may be formed at the same level on the photoresist layer 74. According to an embodiment of the inventive concept, the second corrugated surface 76 and the second flat surface 78 may be formed by performing a photolithograph process and a reflow process on the photoresist layer 74. For example, the second corrugated surface 76 of the photoresist layer 74 that is formed by the photolithograph process may have a shape that protrudes at a right angle. Also, the rounded second corrugated surface 76 may be formed by the reflow process. According to another embodiment of the inventive concept, the second corrugated surface 76 and the second flat surface 78 may be manufactured by the photolithograph process using a grayscale photomask. Although not shown, the grayscale mask may have half tone masking patterns on a portion corresponding to the second corrugated surface 76 and black and white masking patterns on a portion corresponding to the second flat surface 78.

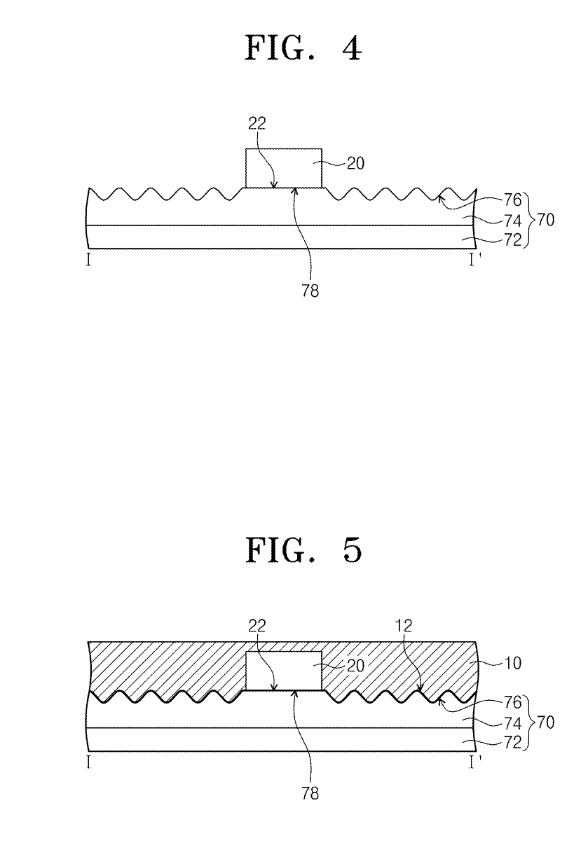

Referring to FIG. 4, a high-stiffness block 20 is bonded on the second flat surface 78 of the mold substrate 70. The high-stiffness block 20 may be formed by using a photolithograph, printing, or bonding method. The high-stiffness block 20 may include a photopatternable resin.

Referring to FIG. 5, a low-stiffness body 10 is formed on the mold substrate 70 and the high-stiffness block 20. The low-stiffness body 10 may be formed by using a spin coating or dropping method. The low-stiffness body 10 may include addition-cure liquid silicone rubber (Sylgard 184).

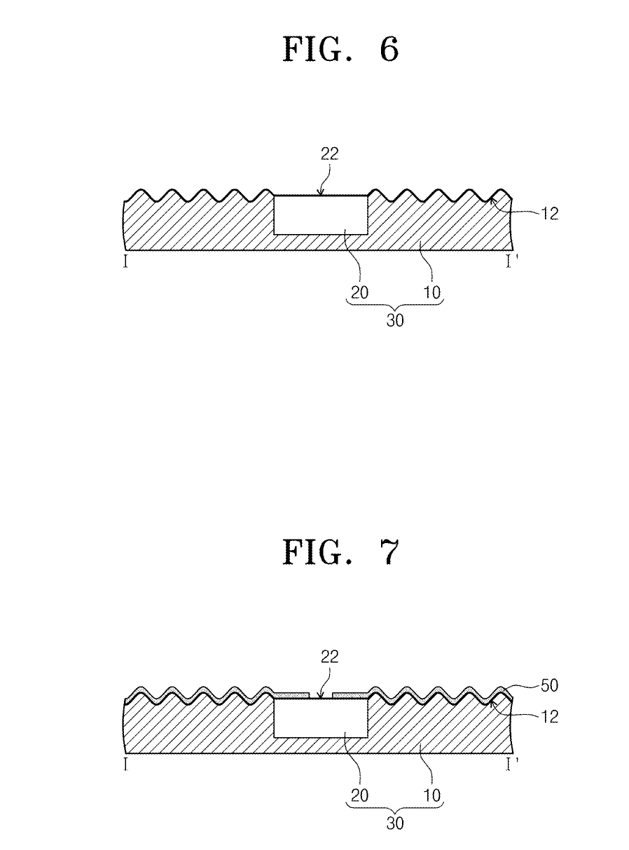

Referring to FIG. 6, the mold substrate 70 is removed. The photoresist layer 74 of the mold substrate 70 may be removed by an organic solvent.

Referring to FIG. 7, corrugated wires 50 are formed on the low-stiffness body 10 and the high-stiffness block 20. The process for forming the corrugated wires 50 may include a metal deposition process, a photolithograph process, and an etching process. The metal deposition process may include a chemical vapor deposition process or a physical vapor deposition process. The corrugated wires 50 may be vertically and horizontally formed along a first corrugated surface 12 of the low-stiffness body 10.

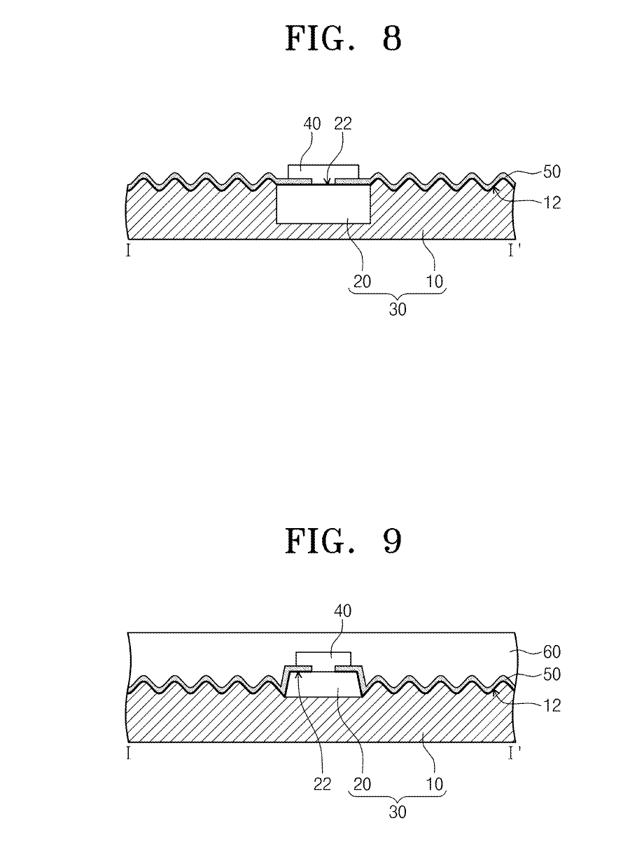

Referring to FIG. 8, an electric device 40 is formed on the high-stiffness block 20. The electric device 40 may be connected to the corrugated wires 50. The process for forming the elastic device 40 may include a deposition process, an ion injection process, a photolithograph process, or an etching process. The first flat surface 22 of the high-stiffness block 20 may be a formation bottom surface of the elastic device 40. The first flat surface 22 may provide a plane on which the electric device 40 is stably formed. Thus, the electric devices 40 may be formed with high reliability.

Referring again to FIG. 2, the stretchable protection layer 60 is formed on the low-stiffness body 10, the high-stiffness blocks 20, the electric device 40, and the corrugated wires 50. The stretchable protection layer 60 may be formed by using a chemical vapor deposition process, a physical vapor deposition process, a spin coating process, a sol-gel process, or a printing process. The stretchable protection layer 60 may include an elastomer, a polymer, an elastic thin film, or an organic thin film.

(Second Embodiment)

FIG. 9 is a cross-sectional view of a stretchable electric circuit according to another embodiment of the inventive concept.

Referring to FIG. 9, a stretchable electric circuit according to the second embodiment may include a stretchable substrate 30 including a high-stiffness block 20 protruding upward from a low-stiffness body 10. A first corrugated surface 12 of the low-stiffness body 10 may be disposed under a first flat surface 22 of the high-stiffness block 20. An electric device 40 may be disposed on the first flat surface 22, and corrugated wires 50 may be disposed on the first corrugated surface 12. The electric device 40 may be disposed at a level greater than those of the corrugated wires 50. In the second embodiment, the high-stiffness block 20 of the first embodiment protrudes upward from the low-stiffness body 10.

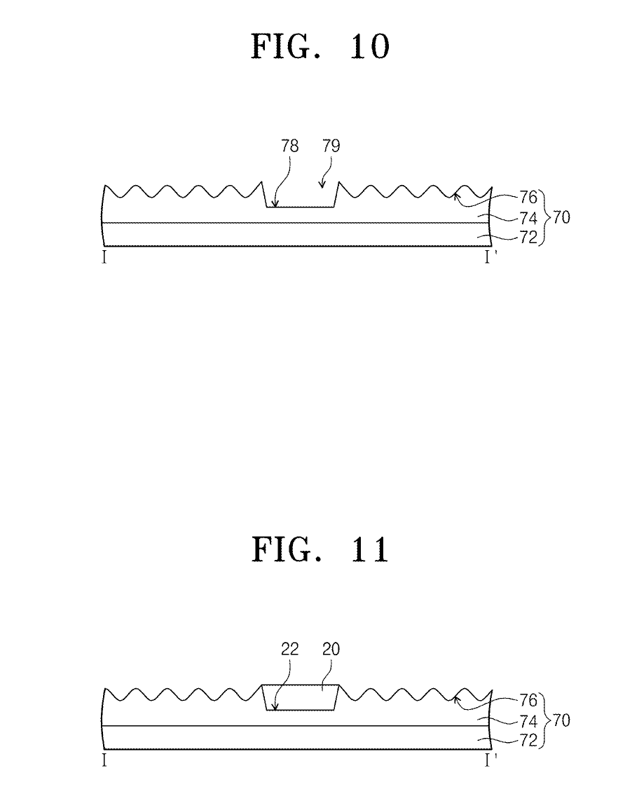

FIGS. 10 to 15 are cross-sectional views of a method for manufacturing the stretchable electric circuit according to the second embodiment of the inventive concept, on the basis of FIG. 9.

Referring to FIG. 10, a mold substrate 70 is prepared. The mold substrate 70 may include a mold body 72 and a photoresist layer 74 formed on the mold body 72. The photoresist layer 74 may have a trench 79. The photoresist layer 74 may have a second corrugated surface 76 and a second flat surface 78. The second flat surface 78 may be disposed under the second corrugated surface 76. The second flat surface 78 may be formed as a bottom of the trench 79. According to an embodiment of the inventive concept, the process for forming the photoresist layer 74 may include a photolithograph process and a reflow process. Also, according to another embodiment of the inventive concept, the process for forming the photoresist layer 74 may include a photolithograph process using a grayscale photomask.

Referring to FIG. 11, a high-stiffness block 20 is formed within the trench 79. The high-stiffness block 20 may include a photopatternable resin.

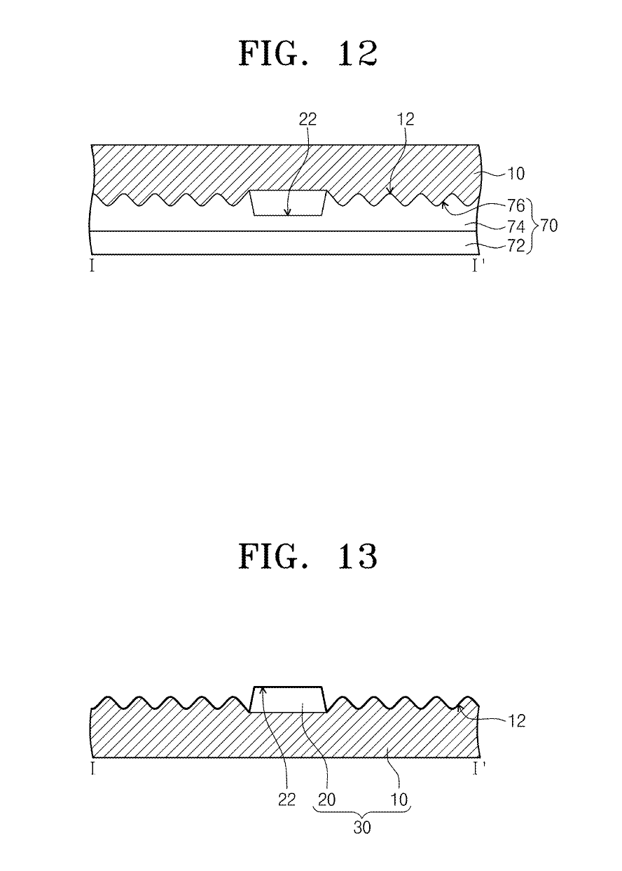

Referring to FIG. 12, a low-stiffness body 10 is formed on the high-stiffness block 20 and the mold substrate 70. The low-stiffness body 10 may be formed by using a spin coating or dropping method. The low-stiffness body 10 may include addition-cure liquid silicone rubber (Sylgard 184).

Referring to FIG. 13, the mold substrate 70 is removed. The photoresist layer 74 of the mold substrate 70 may be removed by an organic solvent.

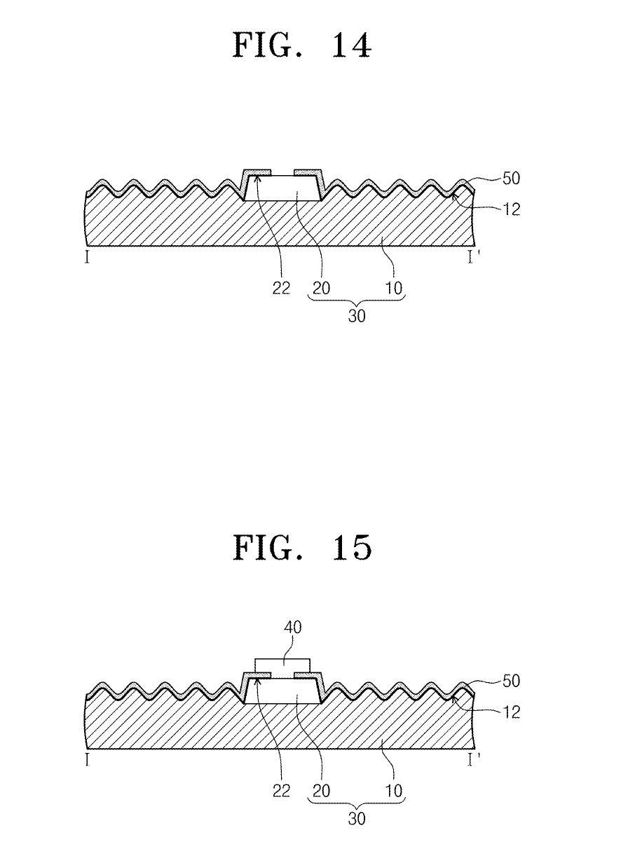

Referring to FIG. 14, the corrugated wires 50 are formed on a portion of the high-stiffness block 20 and on the low-stiffness body 10. The process for forming the corrugated wires 50 may include a metal deposition process, a photolithograph process, and an etching process.

Referring to FIG. 15, the electric device 40 is formed on the high-stiffness block 20. The process for forming the elastic device 40 may include a deposition process, an ion injection process, a photolithograph process, or an etching process. The first flat surface 22 of the high-stiffness block 20 may be a formation bottom surface of the elastic device 40. The first flat surface 22 may provide a plane on which the electric device 40 is stably formed. Thus, the electric devices 40 may be formed with high reliability. The electric device 40 may be disposed at a level greater than those of the corrugated wires 50.

Referring again to FIG. 9, the stretchable protection layer 60 is formed on the low-stiffness body 10, the high-stiffness block 20, the electric device 40, and the corrugated wires 50. The stretchable protection layer 60 may be formed by using a chemical vapor deposition process, a physical vapor deposition process, a spin coating process, a sol-gel process, or a printing process.

(Third Embodiment)

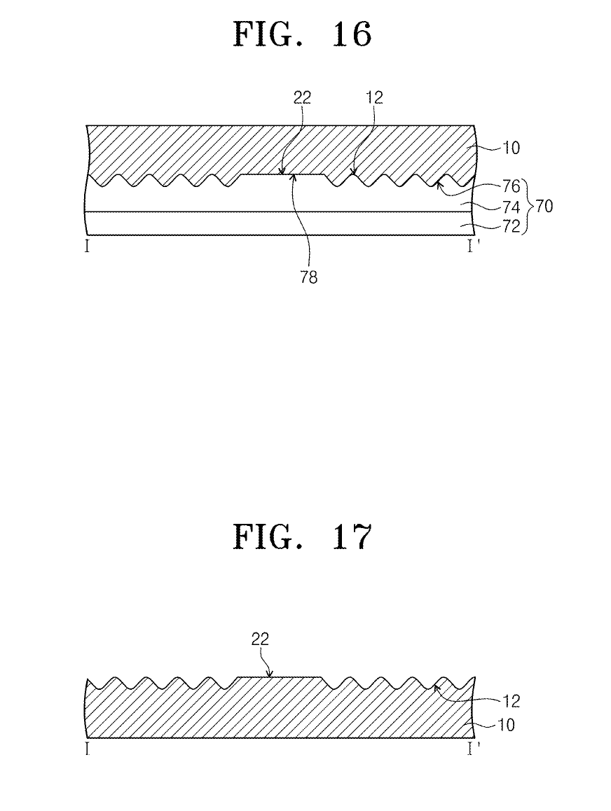

FIGS. 16 to 18 are cross-sectional views of a method for manufacturing an electric circuit according to a third embodiment of the inventive concept.

Referring again to FIG. 3, a mold substrate 70 is prepared. The mold substrate 70 may include a mold body 72 and a photoresist layer 74 formed on the mold body 72. The photoresist layer 74 may have a second corrugated surface 76 and a second flat surface 78. The second corrugated surface 76 and the second flat surface 78 may be formed at the same level on the photoresist layer 74.

Referring to FIG. 16, a low-stiffness body 10 is formed on the mold substrate 70. The low-stiffness body 10 may be formed by using a spin coating or dropping method. The low-stiffness body 10 may include addition-cure liquid silicone rubber (Sylgard 184). The low-stiffness body 10 may have a first corrugated surface 12 and a first corrugated surface 12.

Referring to FIG. 17, the mold substrate 70 is removed. The photoresist layer 74 of the mold substrate 70 may be removed by an organic solvent.

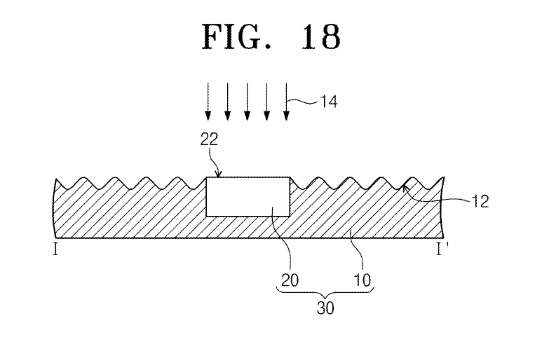

Referring to FIG. 18, a portion of the low-stiffness body 10 formed under the first flat surface 22 is solidified to form a high-stiffness block 20. The high-stiffness block 20 may be formed by using laser light 14.

Referring again to FIG. 7, corrugated wires 50 are formed on the low-stiffness body 10 and the high-stiffness block 20. The process for forming the corrugated wires 50 may include a metal deposition process, a photolithograph process, and an etching process.

Referring again to FIG. 8, an electric device 40 is formed on the high-stiffness block 20. The electric device 40 may be connected to the corrugated wires 50. The process for forming the elastic device 40 may include a deposition process, an ion injection process, a photolithograph process, or an etching process.

Referring again to FIG. 2, a stretchable protection layer 60 is formed on the low-stiffness body 10, the high-stiffness blocks 20, the electric device 40, and the corrugated wires 50. The stretchable protection layer 60 may be formed by using a chemical vapor deposition process, a physical vapor deposition process, a spin coating process, a sol-gel process, or a printing process.

According to the embodiments of the inventive concept, the stretchable substrate may include the low-stiffness body and the high-stiffness block. The corrugated wires may be formed on the low-stiffness body, and the electric device may be formed on the high-stiffness block. The high-stiffness block may improve operation reliability and life cycle of the electric device 40 and facilitate the formation of the electric device.

Until now, preferred embodiments of the inventive concept are described mainly. It will be understood by those skilled in the art that various changes in form and details may be made therein without departing from the spirit and scope of the invention as defined by the appended claims. Therefore, the preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A method for manufacturing a stretchable electric circuit, the method comprising:
forming a mold substrate;
forming a stretchable substrate having a first flat surface and a first corrugated surface outside the first flat surface on the mold substrate;
removing the mold substrate;
forming a corrugated wire on the first corrugated surface; and
forming an electric device connected to the corrugated wire on the first flat surface.

2. The method of claim 1, wherein the stretchable substrate comprises:
a low-stiffness body having the first corrugated surface; and
a high-stiffness block disposed in an island shape on the low-stiffness body, the high-stiffness block having the first flat surface.

3. The method of claim 2, wherein the forming of the stretchable substrate comprises:
forming the high-stiffness block on the mold substrate; and
forming the low-stiffness body on the high-stiffness block and the mold substrate.

4. The method of claim 3, wherein the high-stiffness block is formed by using a photolithograph process, a printing process, or a bonding process.

5. The method of claim 3, wherein the low-stiffness body is formed by using a spin coating process or a dropping process.

6. The method of claim 2, wherein the low-stiffness body is formed of addition-cure liquid silicone rubber.

7. The method of claim 2, wherein the high-stiffness block is formed of a photopatternable resin.

8. The method of claim 2, wherein the low-stiffness body is formed before the mold substrate is removed, and the high-stiffness block is formed after the mold substrate is removed.

9. The method of claim 8, wherein the high-stiffness block is formed by curing the low-stiffness body under the first flat surface by using laser light.

10. The method of claim 2, wherein the mold substrate comprises:
a mold body; and
a photoresist layer disposed on the mold body, and the photoresist layer having a second flat surface corresponding to the first flat surface and a second corrugated surface corresponding to the first corrugated surface.

11. The method of claim 10, wherein the photoresist layer has a trench having the second flat surface under the second corrugated surface, and the high-stiffness block is formed in the trench.

12. The method of claim 1, wherein the forming of the mold substrate comprises a photolithograph process and a reflow process.

13. The method of claim 1, wherein the forming of the mold substrate comprises a photolithograph process using a grayscale photomask.

14. The method of claim 1, further comprising forming a stretchable protection layer on the electric device, the corrugated wire, and the stretchable substrate.

15. A stretchable electric circuit comprising:
a stretchable substrate having a flat surface and a corrugated surface outside the flat surface;
a corrugated wire disposed on the corrugated surface of the stretchable substrate; and
an electric device connected to the corrugated wire, the electric device being disposed on the flat surface,
wherein the flat surface has hardness greater than that of the corrugated surface.

16. The stretchable electric circuit of claim 15, wherein the stretchable substrate comprises an elastomer.

17. The stretchable electric circuit of claim 16, wherein the elastomer comprises poly-dimethyllesiloxane (PDMS) or polyurethane.

18. The stretchable electric circuit of claim 15, wherein the stretchable substrate comprises:
a low-stiffness body having the corrugated surface; and
a high-stiffness block disposed in an island shape on the low-stiffness body, the high-stiffness block having the flat surface.

19. The stretchable electric circuit of claim 18, wherein the low-stiffness body is formed of addition-cure liquid silicone rubber.

20. The stretchable electric circuit of claim 18, wherein the high-stiffness block is formed of a photopatternable resin.
